(19) United States
(12) Patent Application Publication
(10) Pub. No.: US 2026/0130015 A1
(43) Pub. Date: May 7, 2026

(54) LIGHT-EMITTING DIODE

(71) Applicant: Quanzhou sanan semiconductor technology Co., Ltd., Fujian (CN)

(72) Inventors: Meijian WU, Fujian (CN); Jin XU, Fujian (CN); Xiaoyong YAN, Fujian (CN); Zonglin LI, Fujian (CN); Xin CHEN, Fujian (CN); Ke LIU, Fujian (CN)

(73) Assignee: Quanzhou sanan semiconductor technology Co., Ltd., Fujian (CN)

(21) Appl. No.: 19/378,215

(22) Filed: Nov. 3, 2025

(30) Foreign Application Priority Data
Nov. 4, 2024 (CN) 202411562605.X

(51) Int. Cl. H10H 20/832

(52) U.S. Cl. CPC H10H 20/832

(57) ABSTRACT

Provided are a light-emitting diode and a light-emitting device. The light-emitting diode includes an epitaxial structure, a first electrode, and a second electrode. The epitaxial structure includes a first semiconductor layer, an active layer, and a second semiconductor layer alternately stacked in sequence. The first electrode is located on the epitaxial structure and electrically connected to the first semiconductor layer. The second electrode is located on the epitaxial structure and electrically connected to the second semiconductor layer. The first electrode and/or the second electrode has a titanium-free stack structure. Through the above arrangement, an anti-aging capability of a chip may be enhanced, thereby improving the reliability of the chip.

### CROSS-REFERENCE TO RELATED APPLICATION

This application claims the priority benefit of China application serial no. 202411562605.X, filed on Nov. 4, 2024. The entirety of the above-mentioned patent application is hereby incorporated by reference herein and made a part of this specification.

### BACKGROUND

### Technical Field

The disclosure relates to the field of semiconductor technology, and in particular to a light-emitting diode.

### Related Art

Light-emitting diode (LED) is a semiconductor light-emitting element, and is usually made of semiconductors such as GaN, GaAs, GaP, and GaAsP. A core of the LED is a PN junction with a characteristic of light-emitting. The LED has advantages of high luminous intensity, high efficiency, small size, and long service life, and is considered as one of the most potential light sources currently.

The existing LED generally has metallic electrodes including Ti in design. Ti easily causes voids in a fabricating process, resulting in problems of unstable reliability and extremely high abnormal aging rates. Particularly during long-term use, conventional metallic electrodes including Ti in design easily cause accelerated aging of the LED device, reduce luminous efficiency, and even occur failure phenomena. Therefore, how to improve an anti-aging risk of a chip is a major problem that needs to be solved by those skilled in the art currently.

### SUMMARY

To solve at least one deficiency existing in the light-emitting diodes of the prior art, a purpose of the disclosure is to provide a light-emitting diode that can enhance an anti-aging capability of a chip, thereby improving reliability of the chip.

In a first aspect, the disclosure provides a light-emitting diode including an epitaxial structure, a first electrode, and a second electrode. The epitaxial structure includes a first semiconductor layer, an active layer, and a second semiconductor layer alternately stacked in sequence. The first electrode is located on the epitaxial structure and electrically connected to the first semiconductor layer. The second electrode is located on the epitaxial structure and electrically connected to the second semiconductor layer. The first electrode and/or the second electrode is a titanium-free stack structure.

In a second aspect, the disclosure provides a light-emitting diode. The light-emitting diode includes an epitaxial structure, a first contact electrode, a first electrode, a second contact electrode, and a second electrode. The epitaxial structure includes a first semiconductor layer, an active layer, and a second semiconductor layer alternately stacked in sequence. The first contact electrode is located on the epitaxial structure and electrically connected to the first semiconductor layer. The first electrode is located on the first contact electrode and electrically connected to the first contact electrode. The second contact electrode is located on the epitaxial structure and electrically connected to the second semiconductor layer. The second electrode is located on the second contact electrode and electrically connected to the second contact electrode. At least one of the first contact electrode, the first electrode, the second contact electrode, and the second electrode is a titanium-free stack structure.

Based on the above, compared with the prior art, the light-emitting diode provided by the disclosure may effectively avoid the problems of unstable reliability and extremely high abnormal aging rates of electrodes by limiting the material of the electrodes to the titanium-free stack structure, thereby enhancing the reliability and anti-aging capability of the entire chip.

Other features and beneficial effects of the disclosure are described in the subsequent specification, and in part become apparent from the specification, or are learned through implementing the disclosure. The objectives and other beneficial effects of the disclosure may be realized and obtained through the structures particularly pointed out in the specification, claims, and drawings.

### BRIEF DESCRIPTION OF THE DRAWINGS

In order to more clearly illustrate the technical solutions in the embodiments of the disclosure or the prior art, the drawings required for use in the description of the embodiments or the prior art will be briefly described below. Obviously, the drawings in the following description are some embodiments of the disclosure. For those skilled in the art, other drawings may also be obtained based on these drawings without creation. In the following description, the positional relationships described in the drawings, unless specifically indicated, are all based on the direction in which the components are illustrated in the drawings.

FIG. 1 is a cross-sectional view of a light-emitting diode provided by an embodiment in Embodiment 1 of the disclosure.

FIG. 2 is a partial enlarged view of A in FIG. 1.

FIG. 3 is a cross-sectional view of a light-emitting diode provided by another embodiment in Embodiment 1 of the disclosure.

FIG. 4 is a schematic view of a stack structure of a first electrode or a second electrode in FIG. 3.

FIG. 5 is a schematic view of a stack structure of a first electrode or a second electrode provided by another embodiment in Embodiment 1 of the disclosure.

FIG. 6 is a cross-sectional view of a light-emitting diode provided by an embodiment in Embodiment 2 of the disclosure.

FIG. 7 is a partial enlarged view of B in FIG. 6.

FIG. 8 is a cross-sectional view of a light-emitting diode provided by another embodiment in Embodiment 2 of the disclosure.

FIG. 9 is a schematic view of a stack structure of a first contact electrode or a second contact electrode and a first electrode or a second electrode in FIG. 8.

### DESCRIPTION OF THE EMBODIMENTS

To make the objectives, technical solutions, and advantages of the embodiments of the disclosure clearer, the technical solutions in the embodiments of the disclosure will be described clearly and completely below in conjunction with the drawings in the embodiments of the disclosure. Obviously, the described embodiments are part of the embodiments of the disclosure, rather than all embodiments. The technical features designed in different embodiments of the disclosure described below may be combined with each other as long as there is no conflict with each other. Based on the embodiments of the disclosure, all other embodiments obtained by those skilled in the art without creative work fall within the scope of protection of the present invention.

In the description of the disclosure, it should be noted that all terms (including technical terms and scientific terms) used in the disclosure have the same meaning as commonly understood by those skilled in the art to which the disclosure belongs, and should not be understood as limitations to the disclosure. It should be further understood that the terms used in the disclosure should be understood as having meanings consistent with the meanings of these terms in the context of this specification and related fields, and should not be understood in an idealized or overly formal sense, unless explicitly defined as such in the disclosure.

To achieve at least one advantage or other advantages in the disclosure, an embodiment of the disclosure provides a light-emitting diode. The light-emitting diode at least includes an epitaxial structure, a first electrode, and a second electrode. The epitaxial structure includes a first semiconductor layer, an active layer, and a second semiconductor layer stacked in sequence. The first electrode is located on the epitaxial structure and electrically connected to the first semiconductor layer. The second electrode is located on the epitaxial structure and electrically connected to the second semiconductor layer. The first electrode and/or the second electrode is a titanium-free stack structure.

By disposing the electrode as a titanium-free stack structure, the electrode has good quality to avoid voids leading to water vapor corrosion, thereby enhancing the anti-aging capability and reliability of the chip.

In some embodiments, the titanium-free stack structure includes a gold layer on a side farthest from the epitaxial structure. The gold layer has excellent electrical conductivity, chemical stability, and mechanical strength, which helps to enhance current injection efficiency and has good welding performance.

In some embodiments, a thickness of the gold layer is more than 50% of a thickness of the titanium-free stack structure, to achieve an effect of easy welding.

In some embodiments, the titanium-free stack structure at least includes a nickel layer located on a side closest to the epitaxial structure. The nickel layer enables formation of a good interface with a semiconductor material and also blocks dopant components from diffusing from the semiconductor toward the electrode.

In some embodiments, the nickel layer is also located beneath the gold layer and in direct contact with the gold layer, so as to have good adhesion with the gold layer.

In some embodiments, in the titanium-free stack structure, a thickness of the nickel layer located on the side closest to the epitaxial structure is less than thicknesses of other nickel layers, to effectively exert the respective functions.

In some embodiments, in the titanium-free stack structure, the thickness of the nickel layer on the side closest to the epitaxial structure is less than the thicknesses of other single layers, to reduce resistance, improve contact effect with the semiconductor layer, and reduce uneven stress distribution.

In some embodiments, the titanium-free stack structure further includes platinum layers. In the titanium-free stack structure, the nickel layers and the platinum layers are alternately stacked with each other, and the number of alternately stacked pairs ranges from 1 pair to 5 pairs. The nickel layers and the platinum layers alternately stacked may reduce stress within the nickel layers and greatly improve thermal stability of the electrode.

In some embodiments, in the titanium-free stack structure, the total thickness of the nickel layers is no greater than the total thickness of the platinum layers, to improve the influence of nickel layer stress and avoid abnormal gold warping.

The disclosure further provides a light-emitting diode. The light-emitting diode at least includes an epitaxial structure, a first contact electrode, a first electrode, a second contact electrode, and a second electrode.

The epitaxial structure includes a first semiconductor layer, an active layer, and a second semiconductor layer stacked in sequence. The first contact electrode is located on the epitaxial structure and electrically connected to the first semiconductor layer. The first electrode is located on the first contact electrode and electrically connected to the first contact electrode. The second contact electrode is located on the epitaxial structure and electrically connected to the second semiconductor layer. The second electrode is located on the second contact electrode and electrically connected to the second contact electrode. At least one of the first contact electrode, the first electrode, the second contact electrode, and the second electrode is a titanium-free stack structure.

Through the dual electrode design formed by adding the first contact electrode and the second contact electrode and cooperating with electrodes adopting the titanium-free stack structure, the contact electrodes may be further effectively protected to avoid water vapor entry, reduce the abnormal aging rate of the light-emitting diode significantly, and improve the service life of the light-emitting diode.

In some embodiments, the first contact electrode and/or the second contact electrode includes a first bottom layer on the side closest to the epitaxial structure and a first top layer on the side farthest from the epitaxial structure.

In some embodiments, the first bottom layer and the first top layer have the same metallic material.

In some embodiments, the first bottom layer and the first top layer both include a nickel layer. A thickness of the first top layer is no greater than a thickness of the first bottom layer. The above arrangement may reduce contact resistance, improve current transmission efficiency, and enhance thermal stability of the electrode.

In some embodiments, the first contact electrode and/or the second contact electrode further includes platinum layers. The nickel layers and the platinum layers are alternately stacked with each other, and the number of alternately stacked pairs ranges from 1 pair to 5 pairs, to improve thermal stability of the electrode and effectively relieve stress within the nickel layers.

In some embodiments, the total thickness of the platinum layers on the first contact electrode or the second contact electrode is more than 50% of a thickness of the first contact electrode or a thickness of the second contact electrode, so that the electrode has better mechanical strength and corrosion resistance, and also helps to reduce an electromigration phenomenon.

In some embodiments, in the first contact electrode and/or the second contact electrode, a thickness of a single nickel layer located between the first top layer and the first bottom layer is greater than the thickness of the nickel layer located in the first top layer or the first bottom layer, to effectively utilize the different functions of the nickel layers in each layer.

In some embodiments, the thickness of the first contact electrode and/or the thickness of the second contact electrode ranges from 500 Å to 3500 Å.

In some embodiments, the first electrode and/or the second electrode includes a second top layer on the side farthest from the epitaxial structure and a second bottom layer on the side closest to the epitaxial structure.

In some embodiments, a thickness of the second top layer is more than 50% of the thickness of the first electrode or the thickness of the second electrode where the second top layer is located, thereby facilitating soldering.

In some embodiments, the first bottom layer and the second bottom layer have the same metallic material to effectively control current distribution while reducing stress caused by differences in thermal expansion coefficients, and/or, the first top layer and the second bottom layer have the same metallic material, so that the same material may bond more tightly at the interface, which improves connection strength and reduces resistance.

In some embodiments, the second bottom layer includes a nickel layer. The second top layer includes a gold layer.

In some embodiments, the first electrode and/or the second electrode further includes platinum layers. The nickel layers and the platinum layers are alternately stacked with each other, and the number of alternately stacked pairs ranges from 1 pair to 4 pairs.

In some embodiments, the thickness of the first electrode is greater than the thickness of the first contact electrode. The thickness of the second electrode is greater than the thickness of the second contact electrode. The thickness of the first electrode and the thickness of the second electrode ranges from 1 μm to 3 μm. The arrangement helps to improve an electrical characteristic and thermal management.

In some embodiments, the light-emitting diode further includes an insulating layer. The insulating layer covers the epitaxial structure and covers at least part of sidewalls of the epitaxial structure.

In some embodiments, the insulating layer includes a first insulating layer, a second insulating layer, and a third insulating layer which are stacked. A thickness of the first insulating layer is less than a thickness of the second insulating layer. The thickness of the second insulating layer is less than a thickness of the third insulating layer. The thickness of the first insulating layer is less than or equal to 100 Å. Multiple insulating layers in design may further avoid water vapor entry, effectively achieve electrical isolation, and enhance anti-aging capability.

In some embodiments, a size of the light-emitting diode is less than or equal to 150 μm.

The disclosure further provides a light-emitting device adopting the light-emitting diode according to any one of the aforementioned embodiments, to enhance the performance of the light-emitting device.

The technical solutions of the disclosure are clearly and completely described through various specific embodiments in conjunction with the drawings in the embodiments of the disclosure.

### Embodiment 1

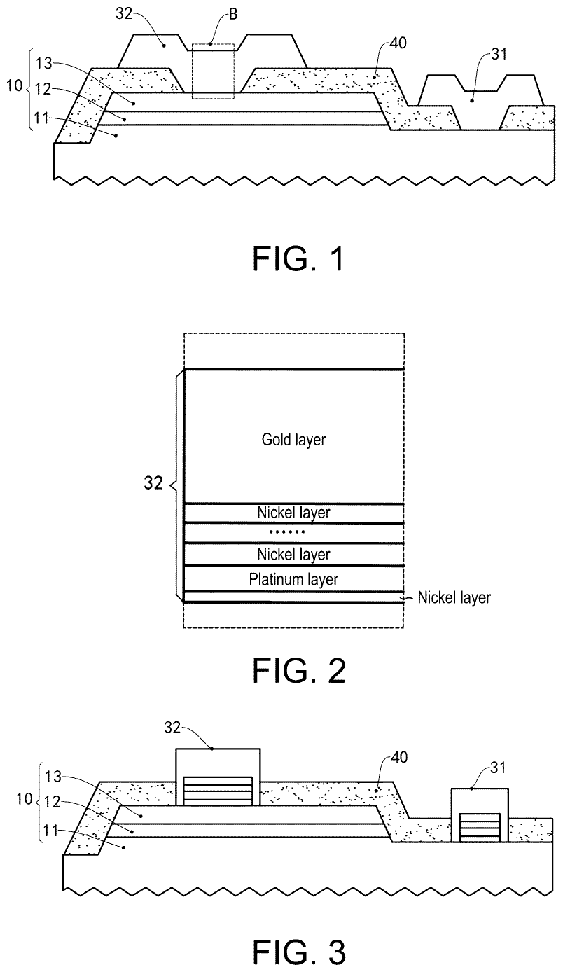

Referring to FIG. 1, FIG. 1 is a cross-sectional view of a light-emitting diode provided by an embodiment of the disclosure. The light-emitting diode provided by this embodiment at least includes an epitaxial structure 10, a first electrode 31, and a second electrode 32.

The epitaxial structure 10 is disposed on a substrate. The substrate may be an insulating substrate. Preferably, the substrate may be made of a transparent material or a translucent material. For example, the substrate is a sapphire substrate or a patterned sapphire substrate. The substrate may also be made of a conductive material or a semiconductor material. For example, the material of the substrate may include at least one of silicon carbide, silicon, magnesium aluminum oxide, magnesium oxide, lithium aluminum oxide, aluminum gallium oxide, and gallium nitride.

The epitaxial structure 10 includes a first semiconductor layer 11, an active layer 12, and a second semiconductor layer 13 stacked in sequence. The first semiconductor layer 11 may be an N-type semiconductor layer, which may provide electrons to the active layer 12 under the action of a power source. In some embodiments, the first semiconductor layer 11 includes an N-type doped nitride layer. The N-type doped nitride layer may include N-type impurities of one or more Group IV elements. The N-type impurities may include one of Si, Ge, Sn, or combinations thereof.

The active layer 12 may be a quantum well (QW) structure. In some embodiments, the active layer 12 may also be a multiple quantum well (MQW) structure. The MQW structure includes multiple quantum well layers and multiple quantum barrier layers alternately disposed in a repetitive manner, which may be, for example, GaN/AlGaN, InAlGaN/InAlGaN, or InGaN/AlGaN. In addition, a composition and thickness of the well layers within the active layer 12 determine the wavelength of the generated light. Improving the luminous efficiency of the active layer 12 may be achieved by changing the depth of the quantum wells, the number of layers of paired quantum wells and quantum barriers, thickness and/or other characteristics in the active layer 12.

The second semiconductor layer 13 may be a P-type semiconductor layer, which may provide holes to the active layer 12 under the action of a power source. In some embodiments, the second semiconductor layer 13 includes a P-type doped nitride layer. The P-type doped nitride layer may include P-type impurities of one or more Group II elements. The P-type impurities may include one of Mg, Zn, Be, or combinations thereof. The second semiconductor layer 13 may be a single-layer structure or a multi-layer structure having different compositions. In addition, the arrangement of the epitaxial structure 10 is not limited thereto, and other functional or types of epitaxial structures may be selected according to actual requirements.

Continuously referring to FIG. 1, the first electrode 31 is located on the epitaxial structure 10 and electrically connected to the first semiconductor layer 11. The second electrode 32 is located on the epitaxial structure 10 and electrically connected to the second semiconductor layer 13. In some embodiments, a current expanding layer 51 may be disposed between the electrode and the epitaxial structure 10 to further enhance conductive performance and strengthen the optoelectronic characteristic of the light-emitting diode. A current barrier layer 52 may also be disposed below the electrode to suppress the current aggregation phenomenon near the electrode and improve current expanding performance. For example, in FIG. 6, a current expanding layer 51 and a current barrier layer 52 are disposed between the second electrode 32 and the epitaxial structure 10. An orthogonal projection of the current barrier layer 52 on the substrate is located within an orthogonal projection of the current expanding layer 51 on the substrate.

Further, the light-emitting diode also includes an insulating layer 40. The insulating layer 40 covers on the epitaxial structure 10 and covers at least part of the sidewalls of the epitaxial structure 10. The insulating layer 40 has different effects according to the disposed position. For example, when covering the sidewalls of the epitaxial structure 10, the insulating layer 40 may be disposed to prevent electrical connection between the first semiconductor layer 11 and the second semiconductor layer 13 due to conductive material leakage, and reduce the possibility of short circuit abnormality of the light-emitting diode, but the embodiments of the disclosure are not limited thereto.

As a preferred solution, in this embodiment, the insulating layer 40 includes a first insulating layer, a second insulating layer, and a third insulating layer stacked in sequence. The thickness of the first insulating layer is less than the thickness of the second insulating layer. The thickness of the second insulating layer is less than the thickness of the third insulating layer. The first insulating layer, the second insulating layer, and the third insulating layer may be silicon oxide passivation layers, organic passivation layers, and DBR stack reflective layers formed by dielectric materials, and specifically stacked with each other according to actual application requirements and technical requirements to achieve different performance targets. The insulating layer 40 having multiple stacking layers may further avoid water vapor entry, effectively achieve electrical isolation, and enhance anti-aging capability.

As an example, the first insulating layer is an ALD layer, the second insulating layer is a PECVD layer, and the third insulating layer is a DBR stack. The ALD layer is a uniform and high-quality insulating interface thin film formed by an atomic layer deposition (ALD) method to protect the chip structure from environmental factors. Preferably, in this embodiment, aluminum oxide is used as the material of the ALD layer. Preferably, a thickness of the ALD layer is equal to or less than 100 Å, for example 50 Å, to avoid an over-etching phenomenon due to excessive thickness of the ALD layer in the subsequent etching process, which may cause damage to the DBR stack, enhance electrical insulation performance, and prevent current leakage. The PECVD layer is an insulating thin film with good mechanical strength and electrical insulation formed by a plasma-enhanced chemical vapor deposition (PECVD) method. Preferably, in this embodiment, silicon oxide or silicon nitride is used as the material of the PECVD layer. As an example, a thickness of the PECVD layer is greater than the thickness of the ALD layer to provide better mechanical protection and higher insulation impedance. Preferably, in this embodiment, the thickness of the PECVD layer is set to range from 1000 Å to 5000 Å, for example 2000 Å. The distributed Bragg reflector (DBR) stack includes a structure composed of multiple layers of materials with different refractive indices arranged alternately, and is configured to reflect light of specific wavelengths, which serves as insulation and also as an optical function to improve light extraction efficiency. A material of the DBR stack is, for example, formed by periodically stacking silicon dioxide and titanium dioxide. Preferably, in this embodiment, a thickness of the DBR stack is set to be greater than the thickness of the PECVD layer to ensure that the DBR stack has a sufficient reflection effect. The thickness of the DBR stack is greater than 5000 Å, for example 8000 Å. Through the above specific design of the insulating layer 40, the electrode may be effectively protected from water vapor erosion, so that the anti-aging performance of the chip is significantly enhanced.

Titanium-containing materials are generally used in traditional metallic electrodes. Such design satisfies the basic light-emitting region of LEDs to a certain extent. However, the titanium materials are easily corroded in the subsequent etching process, causing voids, which leads to problems of unstable reliability and extremely high abnormal aging rates of the light-emitting diode during long-term use.

Based on the above, the design of the first electrode 31 and the second electrode 32 in this embodiment solves the aforementioned problems. Specifically, in this embodiment, the first electrode 31 and/or the second electrode 32 is a titanium-free stack structure, so that the electrode has good quality to avoid voids that may cause water vapor erosion, fundamentally solve the problem of abnormal aging, and improve the reliability of the light-emitting diode.

In a preferred embodiment, the titanium-free stack structure includes a gold layer farthest from the epitaxial structure 10. The gold layer has excellent electrical conductivity, chemical stability, mechanical strength, and good welding performance. Disposing the gold layer on the outermost layer of the titanium-free stack structure helps enhance current injection efficiency, prevents the electrode material from being corroded in manufacturing and use processes, and further improves the performance and reliability of the device. To ensure that the gold layer has the good performance and achieves an easy welding effect, preferably, in this embodiment, the thickness of the gold layer is more than 50% of the thickness of the titanium-free stack structure. More preferably, the thickness of the gold layer is more than 60% or 80% to 90% of the thickness of the titanium-free stack structure.

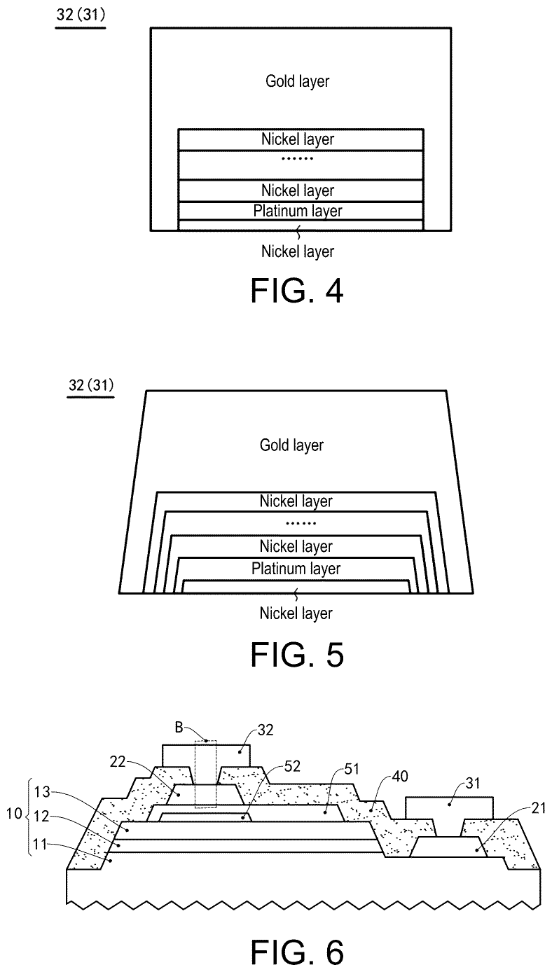

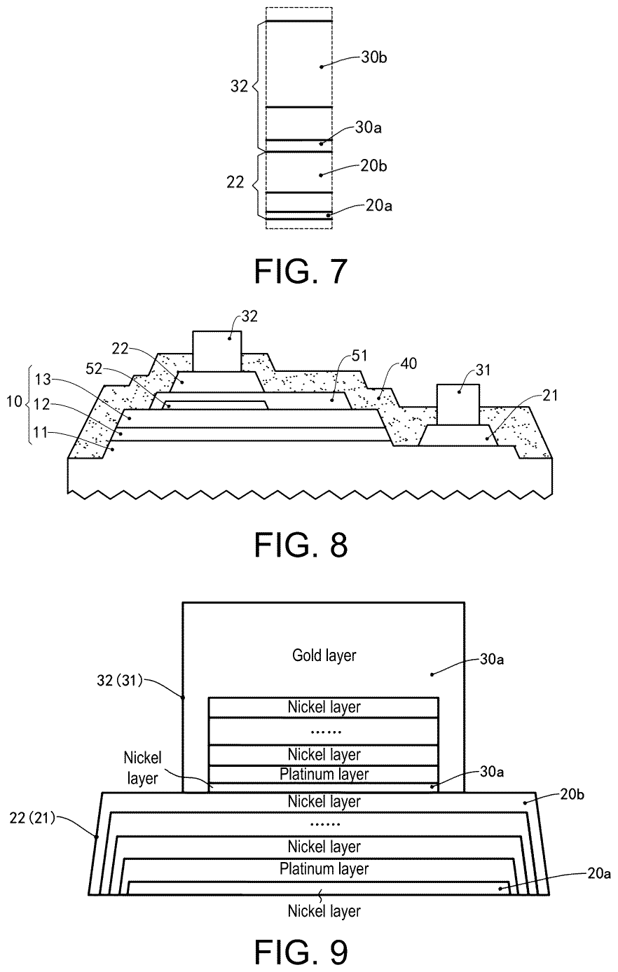

Furthermore, in the first electrode 31 or the second electrode 32, the gold layer located on the outermost side is disposed to cover other stacks beneath the gold layer, thereby acting to protect the stacks below the gold layer, which effectively achieves anti-oxidation and anti-corrosion of the electrode. In some specific implementations, only the gold layer covers the below stacks, as shown in FIG. 4, or each stack covers the below stacks, as shown in FIG. 5, which further ensures good performance of the electrode. Meanwhile, a cross-sectional outer contour of the first electrode 31 and/or a cross-sectional outer contour of the second electrode 32 may be disposed as a rectangular shape as shown in FIG. 4 or a trapezoidal shape with slopes as shown in FIG. 5. Certainly, other regular or irregular shapes may also be disposed according to actual requirements, and this embodiment is not limited thereto.

In another preferred embodiment, please continue to refer to FIG. 2, FIG. 4, and FIG. 5. The titanium-free stack structure at least includes a nickel layer located on a side closest to the epitaxial structure 10. If this layer uses conventional chromium as a contact layer (the layer usually in direct contact with the semiconductor layer), extremely high abnormal aging rates may easily occur. Therefore, in this embodiment, the layer on the side closest to the epitaxial structure 10 is a nickel layer. The nickel layer may form a good interface with semiconductor materials, reduce interface defects, and also act as a barrier layer to prevent or reduce diffusion of doping components from the semiconductor layer to the metallic layer. In addition, the nickel layer also has good heat dissipation, electrical conductivity, water vapor resistance, and anti-aging performance, which effective resists high-temperature aging while ensuring electrical conductivity performance. Certainly, the layer on the side closest to the epitaxial structure 10 may also use other materials, such as niobium.

Preferably, the nickel layer is also located beneath the gold layer and in direct contact with the gold layer. The gold layer and the below nickel layer may form good adhesion, helping to enhance the mechanical stability of the entire metallic stack structure. Certainly, the layer structure in direct contact with the gold layer may also be other materials such as a copper layer, and an aluminum layer, besides the nickel layer.

Furthermore, in the titanium-free stack structure, the thickness of the nickel layer on the side closest to the epitaxial structure 10 is less than the thicknesses of other single layers. By disposing a thinner nickel layer as the contact layer, resistance may be reduced, contact effect with the semiconductor layer may be improved, and current transmission efficiency of the light-emitting diode may be enhanced. At the same time, thermal conduction may also be controlled, uneven stress distribution caused by thermal expansion coefficient mismatch may be reduced, and the risk of damage to the semiconductor layer may be lowered.

The titanium-free stack structure may further include an intermediate layer located between the bottom layer and the top layer. A material of the intermediate layer may be a Ni/Pt stack. As an example, the thickness of the bottom layer ranges from 10 Å to 50 Å.

Preferably, please continue to refer to FIG. 2, FIG. 4, and FIG. 5. The titanium-free stack structure further includes multiple platinum layers. In the titanium-free stack structure, the nickel layers and the platinum layers are alternately stacked with each other, and the number of pairs of alternate stacks ranges between 1 pair to 5 pairs. Disposing the nickel layers and the platinum layers alternately stacked may greatly improve the thermal stability of the electrode, apply in high-temperature environments for long-term, and enhance the service life of the device. Since the nickel layer has greater stress compared to other metallic layers, the nickel layers and the platinum layers alternately disposed may reduce the stress within the nickel layers. At the same time, by further adjusting the thicknesses of the nickel layers and disposing the total thickness of the nickel layers to be no greater than the total thickness of the platinum layers, the influence of nickel layer stress may be further improved, subsequent gold warping abnormalities may be avoided, and thereby the quality of the electrode may be enhanced.

Furthermore, in the titanium-free stack structure, the thickness of the nickel layer located on the side closest to the epitaxial structure 10 is less than the thicknesses of other nickel layers. Based on the different functions of the nickel layer on the side closest to the epitaxial structure 10 compared to other nickel layers, adjusting the thickness of the nickel layer on the side closest to the epitaxial structure 10 to be less than the thickness of other nickel layers may effectively enable each to perform the respective functions. Specifically, disposing a thinner nickel layer on the side closest to the epitaxial structure 10 may reduce thermal stress generated between the thinner nickel layer and the epitaxial structure 10 due to differences in thermal expansion coefficients, thereby improving the stability and reliability of the electrode. While disposing thicker nickel layers at other positions in the titanium-free stack structure may provide sufficient mechanical strength, conductivity, and corrosion resistance.

More preferably, the size of the light-emitting diode in Embodiment 1 is preferably less than or equal to 150 μm. That is, this embodiment is applicable to conventional LEDs, and also applicable to micro LEDs, to effectively enhance the high-temperature resistance, high-humidity resistance, and aging performance of the micro LEDs.

### Embodiment 2

Please refer to FIG. 6. Different from Embodiment 1, Embodiment 2 adopts a dual-electrode structure, that is, a first contact electrode 21 is added between the first electrode 31 and the epitaxial structure 10, and a second contact electrode 22 is added between the second electrode 32 and the epitaxial structure 10. In specific implementation, the light-emitting diode includes an epitaxial structure 10, a first contact electrode 21, a first electrode 31, a second contact electrode 22, and a second electrode 32.

The epitaxial structure 10 includes a first semiconductor layer 11, an active layer 12, and a second semiconductor layer 13 stacked in sequence. The first contact electrode 21 is located on the epitaxial structure 10 and electrically connected to the first semiconductor layer 11. The second contact electrode 22 is located on the epitaxial structure 10 and electrically connected to the second semiconductor layer 13. Certainly, this embodiment further includes an insulating layer 40. The insulating layer 40 also includes a first insulating layer, a second insulating layer, and a third insulating layer. The functions and characteristics of the aforementioned structures may refer to those described in Embodiment 1, and are not repeated.

In this embodiment, the first electrode 31 is located on the first contact electrode 21 and electrically connected to the first contact electrode 21. The second electrode 32 is located on the second contact electrode 22 and electrically connected to the second contact electrode 22. At least one of the first contact electrode 21, the first electrode 31, the second contact electrode 22, and the second electrode 32 is a titanium-free stack structure. That is, the material of the dual-layer electrode does not contain titanium.

Through the dual-electrode design formed by adding the first contact electrode 21 and the second contact electrode 22 and cooperating with the electrode adopting a titanium-free stack structure, the electrode may be further effectively protected to avoid water vapor entry, reduce the aging abnormality rate of the light-emitting diode significantly, and improve the service life of the light-emitting diode.

Optionally, a thickness of the first electrode 31 is greater than a thickness of the first contact electrode 21. A thickness of the second electrode 32 is greater than a thickness of the second contact electrode 22. The first electrode 31 and the second electrode 32, which are thicker than the first contact electrode 21 and the second contact electrode 22, may not only provide greater current capacity and help optimize current distribution in the electrode, but also provide better thermal conduction paths to improve thermal management. In addition, the first electrode 31 and the second electrode 32 may also better resist mechanical stress encountered in manufacturing and use processes. As an example, the thickness of the first electrode 31 and the thickness of the second electrode 32 ranges from 1 μm to 3 μm. The thickness of the first contact electrode 21 and/or the thickness of the second contact electrode 22 ranges from 500 Å to 3500 Å.

As a preferred solution, the first contact electrode 21 and/or the second contact electrode 22 includes a first bottom layer 20a on the side closest to the epitaxial structure 10 and a first top layer 20b on the side farthest from the epitaxial structure 10. A thickness of the first top layer 20b is not greater than a thickness of the first bottom layer 20a. Specifically, the first top layer 20b needs to achieve contact with the first electrode 31 or the second electrode 32. By disposing the first top layer 20b thinner than the first bottom layer 20a, contact resistance may be reduced, current transmission efficiency may be improved, and thermal stability of the electrode may also be enhanced. In addition, by controlling the thinner thickness of the first top layer 20b, the influence of etching rate on the electrode structure may also be avoided.

Further, the first bottom layer 20a and the first top layer 20b have the same metallic material. As an example, the first bottom layer 20a and the first top layer 20b both include a nickel layer, to avoid outward diffusion of stack material between the first bottom layer 20a and the first top layer 20b, while avoiding inward diffusion of external material into the first bottom layer 20a and the first top layer 20b. In addition, the material of the first bottom layer 20a may also be chromium. The stack material between the first bottom layer 20a and the first top layer 20b includes but is not limited to metals or alloys such as aluminum, copper, nickel, and platinum.

As another preferred solution, the first contact electrode 21 and/or the second contact electrode 22 further includes platinum layers. The nickel layers and the platinum layers are alternately stacked with each other, and the number of alternately stacked pairs ranges from 1 to 5 pairs. Specifically, this arrangement may greatly improve the thermal stability of the electrode, and also help relieve stress within the nickel layers. Moreover, the alternate stacks may improve current distribution in the electrode and reduce local hot spots.

Preferably, the total thickness of the platinum layers on the first contact electrode 21 or the second contact electrode 22 is more than 50% of the thickness of the first contact electrode 21 or the thickness of the second contact electrode 22. Pt has better mechanical strength and wear resistance than Ni. By disposing the total thickness of the platinum layers to be more than 50% of the entire electrode thickness, the mechanical stability of the electrode may be improved, deformation in manufacturing and use processes may be prevented, and electromigration phenomena may also be reduced.

Further, in the first contact electrode 21 and/or the second contact electrode 22, the thickness of the single nickel layer located between the first top layer 20b and the first bottom layer 20a is greater than the thickness of the nickel layer located in the first top layer 20b or the first bottom layer 20a, whereby the different functions of the nickel layers in each layer may be effectively utilized. Specifically, the thinner nickel layers in the first top layer 20b and the first bottom layer 20a may reduce stress and lower contact resistance. While the thicker single nickel layer between the first top layer 20b and the first bottom layer 20a may provide sufficient mechanical strength, conductivity, and corrosion resistance.

In other alternative embodiments, the first electrode 31 and/or the second electrode 32 includes a second top layer 30b on the side farthest from the epitaxial structure 10 and a second bottom layer 30a on the side closest to the epitaxial structure 10. In this embodiment, the second bottom layer 30a preferably includes a nickel layer. The second top layer 30b includes a gold layer. The nickel layer included in the second bottom layer 30a has good adhesion, ensures good attachment between stacks, and prevents detachment in subsequent process or use of the device. Meanwhile, the nickel layer may also improve interface characteristics between the dual-layer electrodes, reduce interface resistance, and prevent interdiffusion of materials between the dual-layer electrodes. The gold layer included in the second top layer 30b has excellent electrical conductivity, chemical stability, mechanical strength, and good soldering performance.

In this embodiment, a thickness of the second top layer 30b is preferably more than 50% of a thickness of the first electrode 31 or a thickness of the second electrode 32 where the second top layer 30b is located, thereby facilitating soldering. More preferably, the thickness of the second top layer 30b is more than 60% or 80% to 90% of the thickness of the first electrode 31 or the thickness of the second electrode 32 where the second top layer 30b is located.

Certainly, the second bottom layer 30a and the second top layer 30b may also use other metal or alloy layers. For example, the second bottom layer 30a may use tungsten, tantalum, and so on. The second top layer 30b may use platinum, tin, and so on. This embodiment is not limited thereto. In this embodiment, the second bottom layer 30a preferably does not include chromium. Chromium has relatively poor contact properties, and when applied in the second bottom layer 30a of the first electrode 31 or the second bottom layer 30a of the second electrode 32, voltage rise may easily occur and lead to high voltage. Also, chromium may easily transfer under high temperature and high pressure conditions, causing chromium failure. Therefore, the second bottom layer 30a preferably includes a nickel layer here, as the nickel layer has good contact properties and does not have the aforementioned problems.

Preferably, the first bottom layer 20a and the second bottom layer 30a have the same metallic material, and/or the first top layer 20b and the second bottom layer 30a have the same metallic material. Disposing the first bottom layer 20a and the second bottom layer 30a as the same metallic material may effectively control current distribution while reducing stress caused by differences in thermal expansion coefficients. In addition, disposing the first top layer 20b and the second bottom layer 30a as the same metallic material enables the same material to bond more tightly at the interface, enhancing the connection strength between the first electrode 31 and the first contact electrode 21 or between the second electrode 32 and the second contact electrode 22, which helps to prevent interface delamination or failure due to mechanical stress or chemical corrosion during use. Meanwhile, the first top layer 20b and the second bottom layer 30a of the same metallic material may provide smoother current transition at the interface, reducing resistance and energy loss, which helps to ensure uniform current distribution in the stack structure. In this embodiment, the first bottom layer 20a, the first top layer 20b, and the second bottom layer 30a preferably include nickel layers to effectively enhance performance.

The first electrode 31 and/or the second electrode 32 further include platinum layers. The nickel layers and the platinum layers are alternately stacked with each other, and the number of alternately stacked pairs ranges from 1 to 4 pairs. As an example, the first electrode 31 and/or the second electrode 32 may form a Ni/Pt/Au structure. In this embodiment, the number of pairs of nickel layers and platinum layers alternately stacked in the first contact electrode 21 is preferably less than the number of pairs of nickel layers and platinum layers alternately stacked in the first electrode 31, and/or the number of pairs of nickel layers and platinum layers alternately stacked in the second contact electrode 22 is less than the number of pairs of nickel layers and platinum layers alternately stacked in the second electrode 32.

Certainly, the stacks between the second bottom layer 30a and the second top layer 30b is not limited to the nickel layers and the platinum layers, but may also be other metals or alloys such as copper and tungsten. In this embodiment, the intermediate bottom layer preferably does not contain an aluminum material.

In addition, in the first electrode 31 and the second electrode 32, the second top layer 30b located on the outermost side is disposed to cover other stacks beneath the second top layer 30b, thereby acting to protect the stacks and effectively achieving anti-oxidation and anti-corrosion of the electrode. In specific implementations, only the second top layer 30b covers the below stacks, as shown in FIG. 9, or the each layer covers the below stacks, further ensuring good performance of the electrode. Similarly, in the first contact electrode 21 and the second contact electrode 22, the stack structures may not cover each other, or only the first top layer 20b may cover the below stacks, or the stack may sequentially cover from top to bottom, as shown in FIG. 9.

Meanwhile, the cross-sectional outer contours of the first electrode 31, the second electrode 32, the first contact electrode 21, and the second contact electrode 22 may be disposed as rectangular or trapezoidal with slopes, and may also be disposed as other regular or irregular shapes according to actual requirements, which is not limited in this embodiment.

Similarly, in Embodiment 2, the size of the light-emitting diode is preferably less than or equal to 150 μm. That is, this embodiment is applicable to conventional LEDs, and also applicable to micro LEDs, to effectively enhance the high-temperature resistance, high-humidity resistance, and aging performance of the micro LEDs.

### Embodiment 3

The disclosure further provides a light-emitting device using the light-emitting diode according to any of the aforementioned embodiments, which may effectively improve the performance of the light-emitting device. The specific structure, function, and effect of the light-emitting diode should refer to the foregoing description, and are not repeated here.

In summary, compared with the prior art, the light-emitting diode and light-emitting device provided by the disclosure may effectively resist water vapor from entering the interior of the light-emitting diode during long-term use through the structural and material design of the electrode, greatly enhance the anti-aging capability of the chip, and have good reliability.

In addition, those skilled in the art should understand that although there are many problems in the prior art, each embodiment or technical solution of the disclosure may only improve in one or several aspects, and does not have to solve all the technical problems listed in the prior art simultaneously. Those skilled in the art should understand that content not mentioned in a claim should not be regarded as a limitation to that claim.

Although terms such as epitaxial structure, first contact electrode, second contact electrode, first electrode, second electrode, and the like are used extensively herein, the possibility of using other terms is not excluded. These terms are used merely for more conveniently describing and explaining the essence of the disclosure. Interpreting the terms as any additional limitations would be contrary to the spirit of the disclosure. The terms “first”, “second”, and the like in the specification and claims of the embodiments of the disclosure and the aforementioned drawings are used to distinguish similar objects, and are not necessarily used to describe a specific order or sequence.

Finally, it should be noted that the above embodiments are only used to illustrate, but not to limit, the technical solutions of the disclosure. Although disclosure has been described in detail with reference to above embodiments, persons skilled in the art should understand that the technical solutions described in the above embodiments may still be modified or some or all of the technical features thereof may be equivalently replaced. However, the modifications or replacements do not cause the essence of the corresponding technical solutions to deviate from the scope of the technical solutions of the embodiments of the disclosure.

What is claimed is:

1. A light-emitting diode, comprising:
an epitaxial structure, comprising a first semiconductor layer, an active layer, and a second semiconductor layer stacked in sequence;
a first electrode, located on the epitaxial structure and electrically connected to the first semiconductor layer; and
a second electrode, located on the epitaxial structure and electrically connected to the second semiconductor layer;
wherein the first electrode and/or the second electrode comprises a titanium-free stack structure.

2. The light-emitting diode according to claim 1, wherein the titanium-free stack structure comprises a gold layer located on a side farthest from the epitaxial structure.

3. The light-emitting diode according to claim 2, wherein a thickness of the gold layer is more than 50% of a thickness of the titanium-free stack structure.

4. The light-emitting diode according to claim 2, wherein the titanium-free stack structure further comprises a first nickel layer located on a side closest to the epitaxial structure.

5. The light-emitting diode according to claim 4, wherein the titanium-free stack structure further comprises at least one second nickel layer located beneath and in direct contact with the gold layer.

6. The light-emitting diode according to claim 5, wherein a thickness of the first nickel layer is less than a thickness of the at least one second nickel layer.

7. The light-emitting diode according to claim 4, wherein the titanium-free stack structure further comprises at least one metal layer, the first nickel layer is located between the at least one metal layer and the epitaxial structure, and a thickness of the first nickel layer is less than a thickness of the at least one metal layer.

8. The light-emitting diode according to claim 2, wherein the titanium-free stack structure comprises a plurality of nickel layers and a plurality of platinum layers, the plurality of nickel layers and the plurality of platinum layers are alternately stacked with each other, and a number of alternately stacked pairs ranges from 1 pair to 5 pairs.

9. The light-emitting diode according to claim 8, wherein in the titanium-free stack structure, a total thickness of the plurality of nickel layers does not exceed a total thickness of the plurality of platinum layers.

10. A light-emitting diode, comprising:
an epitaxial structure, comprising a first semiconductor layer, an active layer, and a second semiconductor layer stacked in sequence;
a first contact electrode, located on the epitaxial structure and electrically connected to the first semiconductor layer;
a first electrode, located on the first contact electrode and electrically connected to the first contact electrode;
a second contact electrode, located on the epitaxial structure and electrically connected to the second semiconductor layer; and
a second electrode, located on the second contact electrode and electrically connected to the second contact electrode;
wherein at least one of the first contact electrode, the first electrode, the second contact electrode, and the second electrode comprises a titanium-free stack structure.

11. The light-emitting diode according to claim 10, wherein the first contact electrode and/or the second contact electrode comprises a first bottom layer on a side closest to the epitaxial structure and a first top layer on a side farthest from the epitaxial structure.

12. The light-emitting diode according to claim 11, wherein the first bottom layer and the first top layer comprise a nickel layer, and a thickness of the first top layer is not greater than a thickness of the first bottom layer.

13. The light-emitting diode according to claim 12, wherein the first contact electrode and/or the second contact electrode further comprises a plurality of platinum layers, a plurality of nickel layers and the plurality of platinum layers are alternately stacked with each other, and a number of alternately stacked pairs ranges from 1 pair to 5 pairs.

14. The light-emitting diode according to claim 13, wherein a total thickness of the plurality of platinum layers on the first contact electrode or the second contact electrode is more than 50% of a thickness of the first contact electrode or a thickness of the second contact electrode.

15. The light-emitting diode according to claim 13, wherein in the first contact electrode and/or the second contact electrode, a thickness of a single nickel layer located between the first top layer and the first bottom layer is greater than a thickness of a single nickel layer located in the first top layer or the first bottom layer.

16. The light-emitting diode according to claim 11, wherein the first electrode and/or the second electrode comprises a second top layer on a side farthest from the epitaxial structure and a second bottom layer on a side closest to the epitaxial structure.

17. The light-emitting diode according to claim 12, wherein a thickness of the second top layer is more than 50% of a thickness of the first electrode or a thickness of the second electrode in which the second top layer is located.

18. The light-emitting diode according to claim 16, wherein the first bottom layer and the second bottom layer have the same metallic material, and/or the first top layer and the second bottom layer have the same metallic material.

19. The light-emitting diode according to claim 16, wherein the second bottom layer comprises a nickel layer, and the second top layer comprises a gold layer.

20. The light-emitting diode according to claim 19, wherein the first electrode and/or the second electrode further comprises a plurality of platinum layers, a plurality of nickel layers and the plurality of platinum layers are alternately stacked, and a number of alternately stacked pairs ranges from 1 pair to 4 pairs.
